(19) United States
(12) Patent Application Publication
(10) Pub. No.: US 2024/0260215 A1
(43) Pub. Date: Aug. 1, 2024

(54) HOUSING STRUCTURE

(71) Applicant: JVCKENWOOD Corporation, Yokohama-shi (JP)

(72) Inventor: Yoji Kimura, Yokohama-shi (JP)

(21) Appl. No.: 18/631,108

(22) Filed: Apr. 10, 2024

Related U.S. Application Data
(63) Continuation of application No. PCT/JP2022/022713, filed on Jun. 6, 2022.

(30) Foreign Application Priority Data
Oct. 13, 2021 (JP) 2021-167896

(51) Int. Cl. H05K 5/02

(52) U.S. Cl. CPC H05K 5/0221

(57) ABSTRACT

A housing structure includes: a reference member; a pin member that is fixed to the reference member and that extends in a predetermined direction; a first positioning hole that is provided for insertion of the pin member in each of multiple first members; and a second positioning hole that is provided for insertion of the pin member in a second member.

### CROSS-REFERENCE TO RELATED APPLICATIONS

This application is a Continuation of PCT International Application No. PCT/JP2022/022713 filed on Jun. 6, 2022 which claims the benefit of priority from Japanese Patent Application No. 2021-167896 filed on Oct. 13, 2021, the entire contents of both of which are incorporated herein by reference.

### FIELD OF THE INVENTION

The present application relates to a housing structure.

### BACKGROUND OF THE INVENTION

Conventionally, for example, Japanese Laid-open Patent Publication No. 2020-159381 discloses a structure in which a stud pin is extended in two directions to determine positions of multiple components.

In Japanese Laid-open Patent Publication No. 2020-159381, the stud pin is inserted in a sheet metal on which the stud pin is fixed, and a first substrate and a second substrate that extend along the sheet metal above and below thereof. In other words, the stud pin determines positions of the first substrate and the second substrate with respect to the sheet metal.

Here, a housing for an electronic device or the like may include multiple substrates that are arranged therein. Connectors that are electrically connected to each other are arranged on the multiple substrates. In a structure of the housing as described above, there is a need to determine positions of the substrates as described above in order to ensure a connected state of each of the connectors. In contrast, in the housing structure, to improve assembly accuracy, there is a demand to determine positions of a certain member, such as an external housing, that is oriented in a different direction from the substrates. However, in the housing structure, for determining positions of a large number of members, the number of components increases, which tends to lead to degrade assembly performance.

### SUMMARY OF THE INVENTION

A housing structure is disclosed.

According to one aspect of the present application, there is provided a housing structure comprising: a reference member; a pin member that is fixed to the reference member and that extends in a predetermined direction; a first positioning hole that is provided for insertion of the pin member in each of multiple first members; and a second positioning hole that is provided for insertion of the pin member in a second member.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of an electronic device to which a housing structure according to one embodiment is applied;

FIG. 2 is a cross-sectional view of the housing structure according to one embodiment;

FIG. 3 is an exploded perspective view of the housing structure according to one embodiment;

FIG. 4 is a partial enlarged perspective view of the housing structure according to one embodiment;

FIG. 5 is a partial enlarged perspective view of another example of the housing structure according to one embodiment;

FIG. 6 is a partial enlarged perspective view of another example of the housing structure according to one embodiment;

FIG. 7 is a partial enlarged perspective view of another example of the housing structure according to one embodiment; and

FIG. 8 is a cross-sectional view of another example of the housing structure according to one embodiment.

### DETAILED DESCRIPTION OF THE INVENTION

Modes (hereinafter, referred to as embodiments) for carrying out the present application will be described in detail below with reference to the drawings. The present application is not limited by the embodiments described below. Further, the components in the embodiments described below include one that can easily be thought of by a person skilled in the art, one that is practically identical, and one that is within an equivalent range. Furthermore, the components disclosed in the embodiments below may be combined appropriately.

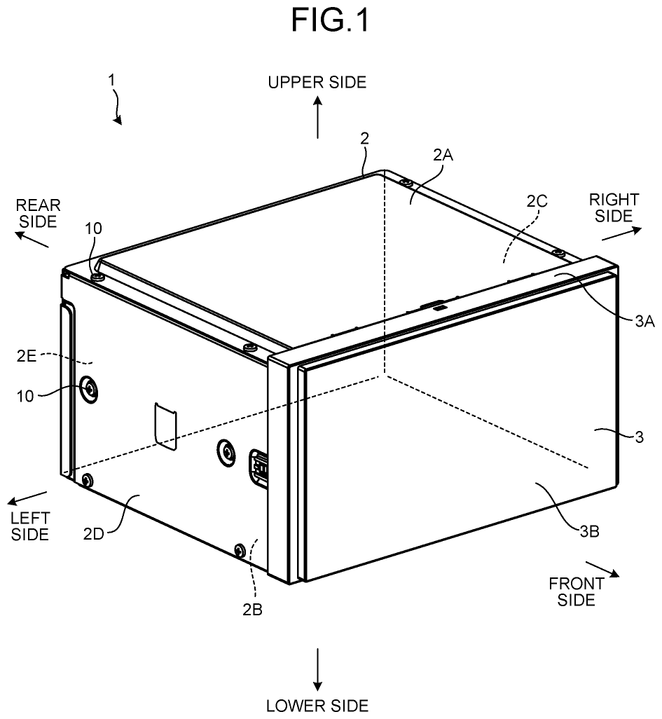

As illustrated in FIG. 1 to FIG. 3, a housing structure according to the present embodiment is applied to an electronic device 1. The electronic device 1 is mounted inside a vehicle, and is, for example, a navigation system or an audio system. The electronic device 1 includes a housing 2 and a display panel 3.

The housing 2 has a structure in which a front side is opened, and an upper side, a lower side, a right side, a left side, and a rear side are closed by metal sheets. Therefore, the housing 2 includes an upper plate 2A, a lower plate 2B, a right plate 2C, a left plate 2D, and a rear plate 2E, which are external housing members that constitute an external frame, and the entire housing is formed in a rectangular parallelepiped manner. Specifically, the housing 2 includes the upper plate 2A and the lower plate 2B, which are arranged parallel to each other with plate surfaces being oriented in an up-down direction, the right plate 2C and the left plate 2D, which are arranged parallel to each other with plate surfaces being oriented in a left-right direction, and the rear plate 2E that is arranged with a plate surface being oriented in a front-back direction. Therefore, the right plate 2C, the left plate 2D, and the rear plate 2E are arranged perpendicular to the upper plate 2A and the lower plate 2B and oriented in different directions. The upper plate 2A, the lower plate 2B, the right plate 2C, the left plate 2D, and the rear plate 2E are assembled by screws 10. Here, the front side, the upper side, the lower side, the right side, the left side, and the rear side of the electronic device 1 define respective directions when the electronic device 1 is mounted ahead of a driver seat of a vehicle. Specifically, it is assumed that a side facing the driver seat side is defined as the “front side”, a side facing a windshield on a front side of the vehicle is defined as the “rear side”, and the right side and the left side are directions when the electronic device 1 is viewed from the front side. Further, the housing 2 is arranged inside a vehicle cluster (also referred to as a dashboard).

The display panel 3 is installed on the front side of the housing 2 such that a panel surface is oriented to the front side. The display panel 3 includes a panel frame 3A and a display unit 3B that serves as the panel surface. The panel frame 3A covers the front side of the housing 2 and is made of synthetic resin. In the present embodiment, the panel frame 3A is slightly larger than the housing 2 in the up-down direction and the left-right direction. The display unit 3B is smaller than the panel frame 3A in the up-down direction and the left-right direction, and is housed inside the panel frame 3A in the up-down direction and the left-right direction. Meanwhile, although not illustrated in the drawings, it may be possible to arrange operation buttons for performing various kinds of operation on the electronic device 1, on the panel frame 3A in the up-down direction or the left-right direction. The display unit 3B includes, for example, a liquid crystal display (LCD) or an Organic Electro-Luminescence (EL) display. Meanwhile, although not illustrated in the drawings, the display unit 3B may be configured as a touch panel.

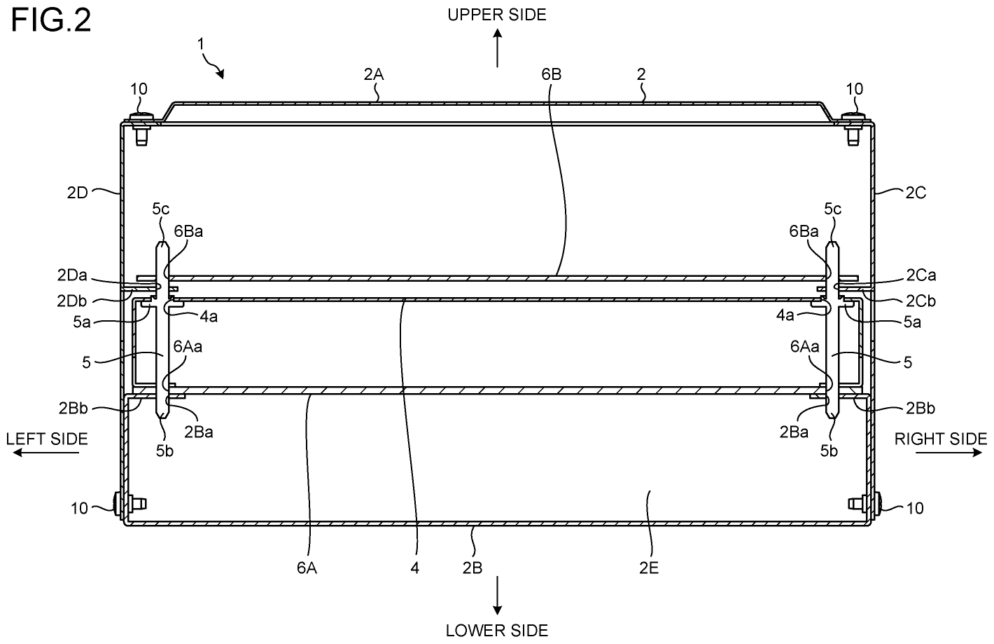

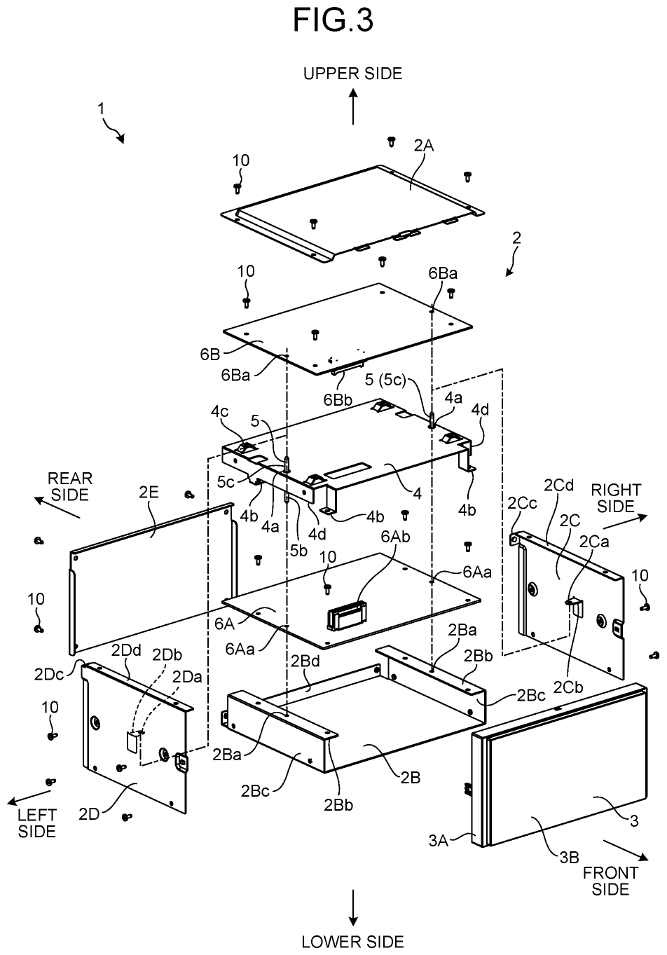

In the electronic device 1, as illustrated in FIG. 2 and FIG. 3, multiple substrates (first members) 6A and 6B are housed inside the housing 2. In the embodiment, the two substrates 6A and 6B are arranged. The substrates 6A and 6B are arranged such that plate surfaces are oriented in the up-down direction and so as to be parallel to the upper plate 2A and the lower plate 2B. In other words, the substrates 6A and 6B are arranged perpendicular to the right plate 2C, the left plate 2D, and the rear plate 2E and oriented in different directions. The substrates 6A and 6B include, as illustrated in FIG. 3, connectors 6Ab and 6Bb that are fitted to each other, and the substrates 6A and 6B are electrically connected to each other when the connectors 6Ab and 6Bb are fitted to each other. In the electronic device 1 according to one embodiment, positions of the substrates 6A and 6B are determined by the housing structure of the embodiment such that the connectors 6Ab and 6Bb are infallibly fitted to each other.

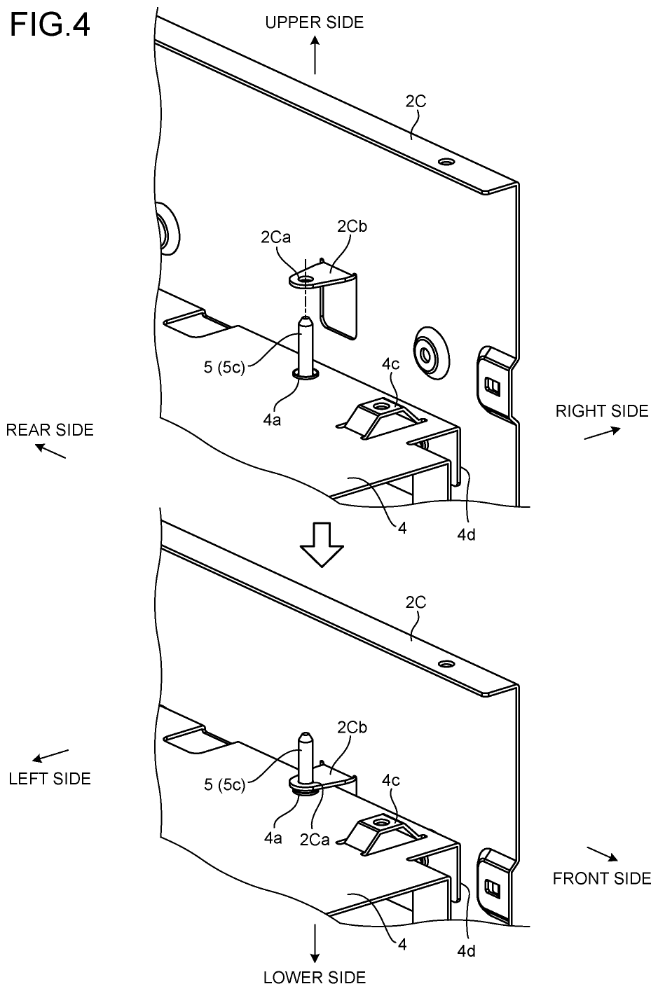

The housing structure according to one embodiment includes, as illustrated in FIG. 2 to FIG. 4, a reference member 4, pin members 5, first positioning holes 6Aa and 6Ba that are arranged in the substrates 6A and 6B that serve as first members, second positioning holes 2Ca and 2Da that are arranged in the right plate 2C and the left plate 2D that serve as second members, and third positioning holes 2Ba that are arranged in the lower plate 2B that serves as a third member.

The reference member 4 is arranged between the substrates 6A and 6B. The reference member 4 is made of a metal plate, and arranged parallel to the substrates 6A and 6B with a plate surface being oriented in the up-down direction. The reference member 4 includes multiple first contact portions 4b (see FIG. 3) that are formed by cutting, raising, and bending the plate surface along an upper surface of the substrate 6A such that the first contact portions 4b come into contact with the substrate 6A. Each of the first contact portions 4b comes into contact with the upper surface of the substrate 6A, so that the reference member 4 is arranged parallel to the substrate 6A. The substrate 6A is fixed to the first contact portions 4b of the reference member 4 with the screws 10. Furthermore, the reference member 4 includes multiple second contact portions 4c (see FIG. 3) that are formed by cutting, raising, and bending the plate surface along a lower surface of the substrate 6B such that the second contact portions 4c come into contact with the substrate 6B. Each of the second contact portions 4c comes into contact with the lower surface of the substrate 6B, the reference member 4 is arranged parallel to the substrate 6B. The substrate 6B is fixed to the second contact portions 4c of the reference member 4 with the screws 10.

The lower plate 2B is fixed to the reference member 4. The lower plate 2B includes first fixing portions 2Bb (see FIG. 3) that are formed by bending a metal plate along a lower surface of the substrate 6A such that the first fixing portions 2Bb come into contact with the substrate 6A in an assembled state of the housing 2. The first fixing portions 2Bb are formed, as a pair, so as to face each other in the left-right direction. Each of the first fixing portions 2Bb comes into contact with the lower surface of the substrate 6A, so that the lower plate 2B is arranged parallel to the substrate 6A. Further, each of the first fixing portions 2Bb of the lower plate 2B is fixed together with each of the first contact portions 4b of the reference member 4 and the substrate 6A with each of the screws 10.

The right plate 2C and the left plate 2D are fixed to the reference member 4. The reference member 4 includes third contact portions 4d (see FIG. 3) that are formed by bending metal plates along an inner surface of the right plate 2C and an inner surface of the left plate 2D such that the third contact portions 4d come into contact with the right plate 2C and the left plate 2D in the assembled state of the housing 2. The third contact portions 4d are formed on both sides of the reference member 4 in the left-right direction. The inner surfaces of the right plate 2C and the left plate 2D come into contact with the third contact portions 4d of the reference member 4, so that the right plate 2C and the left plate 2D are arranged perpendicular to the reference member 4. Further, the right plate 2C and the left plate 2D are fixed to the third contact portions 4d of the reference member 4 with the screws 10.

Meanwhile, the right plate 2C and the left plate 2D are fixed to the lower plate 2B. The lower plate 2B includes second fixing portions 2Bc (see FIG. 3) that are formed, when forming the first fixing portions 2Bb by bending, bending the metal plate along the inner surface of the right plate 2C and the inner surface of the left plate 2D such that the second fixing portions 2Bc come into contact with the right plate 2C and the left plate 2D. The second fixing portions 2Bc are arranged in a perpendicular manner on both sides of the lower plate 2B in the left-right direction. Further, the right plate 2C and the left plate 2D are fixed to the lower plate 2B with the screws 10 while coming into contact with the second fixing portions 2Bc.

Furthermore, the rear plate 2E is fixed to the right plate 2C, the left plate 2D, and the lower plate 2B. The right plate 2C includes a first fixing portion 2Cc (see FIG. 3) that is formed on an upper rear end side of the right plate 2C by bending a metal plate along an inner surface of the rear plate 2E such that the first fixing portion 2Cc comes into contact with the rear plate 2E. The left plate 2D includes a first fixing portion 2Dc (see FIG. 3) that is formed on an upper rear end side of the left plate 2D by bending a metal plate along the inner surface of the rear plate 2E such that the first fixing portion 2Dc comes into contact with the rear plate 2E. The lower plate 2B includes a third fixing portion 2Bd (see FIG. 3) that is formed on a rear end of the lower plate 2B by bending the metal plate along the inner surface of the rear plate 2E such that the third fixing portion 2Bd comes into contact with the rear plate 2E. Moreover, the rear plate 2E is fixed to the right plate 2C, the left plate 2D, and the lower plate 2B with the screws 10 while coming into contact with the first fixing portion 2Cc, the first fixing portion 2Dc, and the third fixing portion 2Bd.

Furthermore, the upper plate 2A is fixed to the right plate 2C and the left plate 2D. The right plate 2C includes a second fixing portion 2Cd (see FIG. 3) that is formed on an upper edge of the right plate 2C by bending the metal plate in a perpendicular manner along an inner surface of the upper plate 2A such that the second fixing portion 2Cd comes into contact with the upper plate 2A. The left plate 2D includes a second fixing portion 2Dd (see FIG. 3) that is formed on an upper edge of the left plate 2D by bending the metal plate in a perpendicular manner along the inner surface of the upper plate 2A such that the second fixing portion 2Dd comes into contact with the upper plate 2A. Moreover, the upper plate 2A is fixed to the right plate 2C and the left plate 2D with the screws 10 while coming into contact with the second fixing portion 2Cd and the second fixing portion 2Dd.

Each of the pin members 5 is also referred to as a stud pin, and includes a fixing portion 5a, a first shaft portion 5b, and a second shaft portion 5c. The pin members 5 are arranged in the reference member 4 and arranged along the up-down direction that is a predetermined direction in the assembled state of the housing 2. Each of the pin members 5 is configured such that the fixing portion 5a is arranged in the center in the up-down direction, the first shaft portion 5b extends downward from the fixing portion 5a while maintaining a constant diameter, and the second shaft portion 5c extends upward from the fixing portion 5a while maintaining a constant diameter. The fixing portions 5a are fixed to fixing holes 4a that are arranged in the reference member 4. The fixing portions 5a are inserted in the fixing holes 4a and fixed by caulking. Therefore, the pin members 5 are fixed to the reference member 4, the first shaft portions 5b extend perpendicular to a lower plate surface of the reference member 4 below the reference member 4, and the second shaft portions 5c extend perpendicular to the upper plate surface of the reference member 4 above the reference member 4. The pin members 5 are arranged on two portions, one of which is on the right side and the other one of which is on the left side, of the reference member 4.

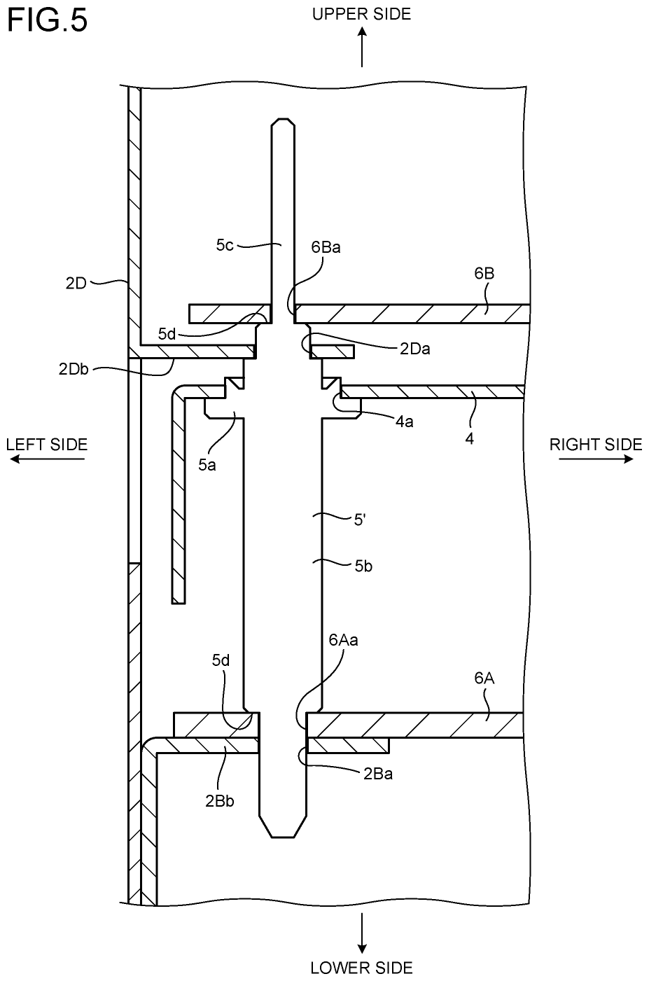

The first positioning holes 6Aa are arranged so as to penetrate through two portions, one of which is on the right side and the other one of which is on the left side, of the substrate 6A. As illustrated in FIG. 5, the first positioning holes 6Aa are arranged so as to allow insertion of the first shaft portions 5b of the pin members 5 when the substrate 6A is fixed to the reference member 4. Therefore, a position of the substrate 6A is determined with respect to the reference member 4 while the first shaft portions 5b of the pin members 5 arranged on the reference member 4 are inserted in the first positioning holes 6Aa.

The first positioning holes 6Ba are arranged so as to penetrate through two portions, one of which is on the right side and the other one of which is on the left side, of the substrate 6B. The first positioning holes 6Ba are arranged so as to allow insertion of the second shaft portions 5c of the pin members 5 when the substrate 6B is fixed to the reference member 4. Therefore, a position of the substrate 6B is determined with respect to the reference member 4 while the second shaft portions 5c of the pin members 5 arranged on the reference member 4 are inserted in the first positioning holes 6Ba.

The second positioning hole 2Ca is arranged so as to penetrate through a positioning piece 2Cb that is formed by cutting, raising, and bending the metal plate of the right plate 2C inwardly in a central portion of the right plate 2C. The positioning piece 2Cb is arranged along the upper plate surface of the reference member 4 in the assembled state of the housing 2. The second positioning hole 2Ca is arranged so as to allow insertion of the second shaft portion 5c of one of the pin members 5 when the housing 2 is assembled. Therefore, a position of the right plate 2C is determined with respect to the reference member 4 while the second shaft portion 5c of the one of the pin members 5 arranged on the reference member 4 is inserted in the second positioning hole 2Ca. Meanwhile, the positioning piece 2Cb is configured by cutting, raising, and bending the metal plate of the right plate 2C, so that it is possible to reduce the number of components. However, for example, the positioning piece 2Cb may be arranged on the right plate 2C by screwing or welding.

The second positioning hole 2Da is arranged so as to penetrate through a positioning piece 2Db that is formed by cutting, raising, and bending the metal plate of the left plate 2D inwardly in a central portion of the left plate 2D. The positioning piece 2Db is arranged along the upper plate surface of the reference member 4 in the assembled state of the housing 2. The second positioning hole 2Da is arranged so as to allow insertion of the second shaft portion 5c of the other one of the pin members 5 when the housing 2 is assembled. Therefore, a position of the left plate 2D is determined with respect to the reference member 4 while the second shaft portion 5c of the other one of the pin members 5 arranged on the reference member 4 is inserted in the second positioning hole 2Da. Meanwhile, the positioning piece 2Db is configured by cutting, raising, and bending the metal plate of the metal plate of the left plate 2D, so that it is possible to reduce the number of components. However, for example, the positioning piece 2Db may be arranged on the left plate 2D by screwing or welding.

The third positioning hole 2Ba is formed so as to penetrate through a central portion of the first fixing portion 2Bb of the lower plate 2B in the front-back direction. The third positioning holes 2Ba are arranged so as to allow insertion of the first shaft portions 5b of the pin members 5 when the lower plate 2B is fixed to the reference member 4. Therefore, a position of the lower plate 2B is determined with respect to the reference member 4 while the first shaft portions 5b of the pin members 5 arranged on the reference member 4 are inserted in the third positioning holes 2Ba.

In the housing structure of one embodiment, the housing 2 is assembled with reference to the reference member 4. Specifically, in an assembly sequence of the housing 2, as for the substrate 6A, as illustrated in FIG. 2 and FIG. 3, the first shaft portion 5b of the pin members 5 on the reference member 4 are inserted in the first positioning holes 6Aa of the substrate 6A, and the substrate 6A is fixed to the reference member 4. Furthermore, when the substrate 6A is fixed to the reference member 4, the second shaft portions 5c of the pin members 5 on the reference member 4 are inserted in the third positioning holes 2Ba of the lower plate 2B, and the lower plate 2B is fixed to the reference member 4 together with the substrate 6B. In this manner, in the housing structure, the positions of the substrate 6A and the lower plate 2B with respect to the reference member 4 are determined by the pin members 5.

As for the right plate 2C, as illustrated in FIG. 2 to FIG. 4, the second shaft portions 5c of the pin members 5 on the reference member 4 are inserted in the second positioning hole 2Ca of the right plate 2C, and the right plate 2C is fixed to the reference member 4. Similarly, as for the left plate 2D, the second shaft portions 5c of the pin members 5 on the reference member 4 are inserted in the second positioning hole 2Da of the left plate 2D, and the left plate 2D is fixed to the reference member 4. Meanwhile, the right plate 2C and the left plate 2D may be fixed to the reference member 4 in reverse order. In this manner, in the housing structure, the positions of the right plate 2C and the left plate 2D with respect to the reference member 4 are determined by the pin members 5. Thereafter, the right plate 2C and the left plate 2D are fixed to the lower plate 2B that is fixed to the reference member 4 together with the substrate 6A as illustrated in FIG. 2 and FIG. 3.

Subsequently, as for the substrate 6B, as illustrated in FIG. 2 and FIG. 3, the second shaft portions 5c of the pin members 5 on the reference member 4 are inserted in the first positioning holes 6Ba of the substrate 6B, and the substrate 6B is fixed to the reference member 4. Furthermore, when the substrate 6B is fixed to the reference member 4, the connectors 6Ab and 6Bb are fitted to each other while the positions of the substrate 6A and the substrate 6B with respect to the reference member 4 are determined by the pin members 5, and the substrate 6A and the substrate 6B are electrically connected to each other. In this manner, in the housing structure, the reference member 4 is arranged between the substrates 6A and 6B, and the positions of the substrates 6A and 6B are determined by the pin members 5 that are arranged on the reference member 4.

Subsequently, the upper plate 2A is fixed to the left plate 2D and the right plate 2C as illustrated in FIG. 2 and FIG. 3. The left plate 2D and the right plate 2C are fixed to the reference member 4 while the positions of the left plate 2D and the right plate 2C are determined, so that the upper plate 2A is fixed to the left plate 2D and the right plate 2C without positional deviation. Further, the rear plate 2E is fixed to the right plate 2C, the left plate 2D, and the lower plate 2B as illustrated in FIG. 3. The right plate 2C, the left plate 2D, and the lower plate 2B are fixed to the reference member 4 while the positions of the right plate 2C, the left plate 2D, and the lower plate 2B are determined, so that the rear plate 2E is fixed to the right plate 2C, the left plate 2D, and the lower plate 2B without positional deviation. Meanwhile, the upper plate 2A and the rear plate 2E may be fixed in reverse order.

Meanwhile, in the housing structure of one embodiment as described above, the example has been described in which the positions of the substrates 6A and 6B are determined and fixed with respect to the housing 2 along the front-rear and left-right directions (horizontal direction), but embodiments are not limited thereto. In the housing structure, for example, it may be possible to determine and fix the positions of the substrates 6A and 6B along the vertical and front-back directions (vertical direction). In this case, in the housing structure, for example, the housing 2 as described above may be configured such that the right plate 2C and the left plate 2D are arranged so as to be oriented in the up-down direction, and the pin members 5 exten in the left-right direction or the front-back direction as a predetermined direction.

FIG. 5 to FIG. 8 illustrate other examples of the housing structure according to one embodiment. In the modes illustrated in FIG. 5 to FIG. 8, configurations of pin members 5′ and 5″ are mainly different from the pin members 5 as described above.

As illustrated in FIG. 5 to FIG. 7, in each of the pin members 5′, stepped portions 5d are arranged in the first shaft portion 5b and the second shaft portion 5c.

In the housing structure according to one embodiment illustrated in FIG. 5, the stepped portions 5d are arranged in portions in which diameters of the first shaft portion 5b and the second shaft portion 5c are reduced in extending directions from the fixing portion 5a. The stepped portions 5d constitute locking surfaces facing downward in the first shaft portions 5b and constitute locking surfaces facing upward in the second shaft portions 5c. In the housing structure according to one embodiment illustrated in FIG. 5, in one of the pin members 5′, the stepped portions 5d are arranged so as to lock a periphery of the second positioning hole 2Ca of the right plate 2C, a periphery of one of the first positioning holes 6Ba of the substrate 6B, and a periphery of one of the first positioning holes 6Aa of the substrate 6A. Furthermore, in the housing structure according to one embodiment illustrated in FIG. 5, in the other one of the pin members 5′, the stepped portions 5d are arranged so as to lock a periphery of the second positioning hole 2Da of the left plate 2D, a periphery of the other one of the first positioning holes 6Ba of the substrate 6B, and a periphery of the other one of the first positioning holes 6Aa of the substrate 6A. Therefore, the housing structure of one embodiment illustrated in FIG. 5 is able to maintain, by the stepped portions 5d, intervals between components through which the pin members 5′ are inserted, and determine positions of the components in the extending directions of the pin members 5′.

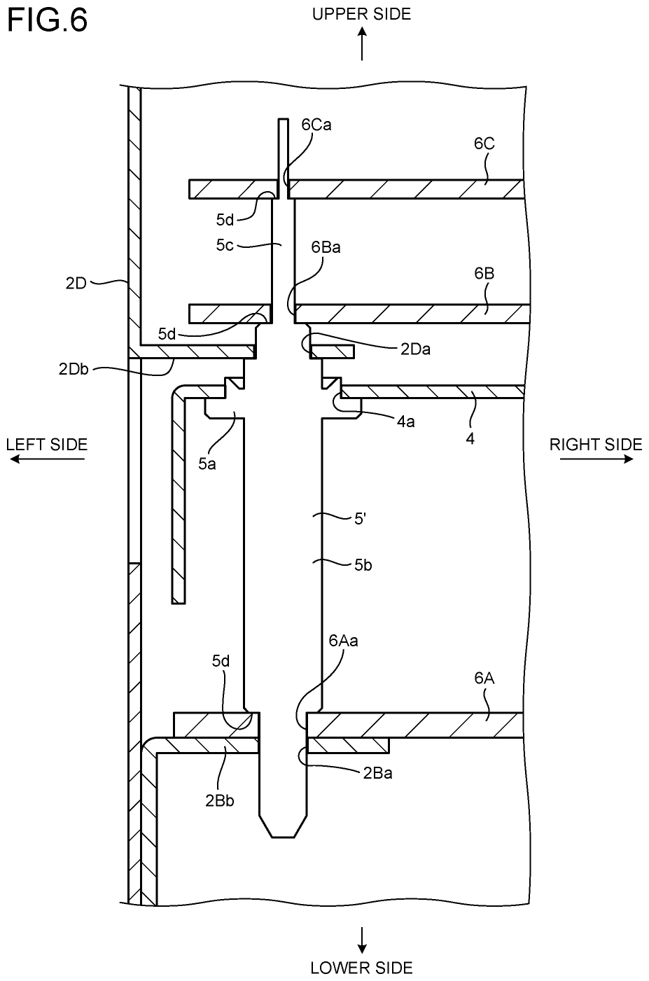

Moreover, a housing structure of one embodiment illustrated in FIG. 6 further includes a substrate 6C above the substrate 6B. In the housing structure according to one embodiment illustrated in FIG. 6, in one of the pin members 5′, the stepped portions 5d are arranged so as to lock the periphery of the second positioning hole 2Ca of the right plate 2C, the periphery of one of the first positioning holes 6Ba of the substrate 6B, a periphery of one of first positioning holes 6Ca of the substrate 6C, and the periphery of one of the first positioning holes 6Aa of the substrate 6A. Furthermore, in the housing structure according to one embodiment illustrated in FIG. 6, in the other one of the pin members 5′, the stepped portions 5d are arranged so as to lock the periphery of the second positioning hole 2Da of the left plate 2D, the periphery of the other one of the first positioning holes 6Ba of the substrate 6B, a periphery of the other one of the first positioning holes 6Ca of the substrate 6C, and the periphery of the other one of the first positioning holes 6Aa of the substrate 6A. Therefore, the housing structure of one embodiment illustrated in FIG. 6 is able to maintain, by the stepped portions 5d, intervals between components through which the pin members 5′ are inserted, and determine positions of the components in the extending directions of the pin members 5′.

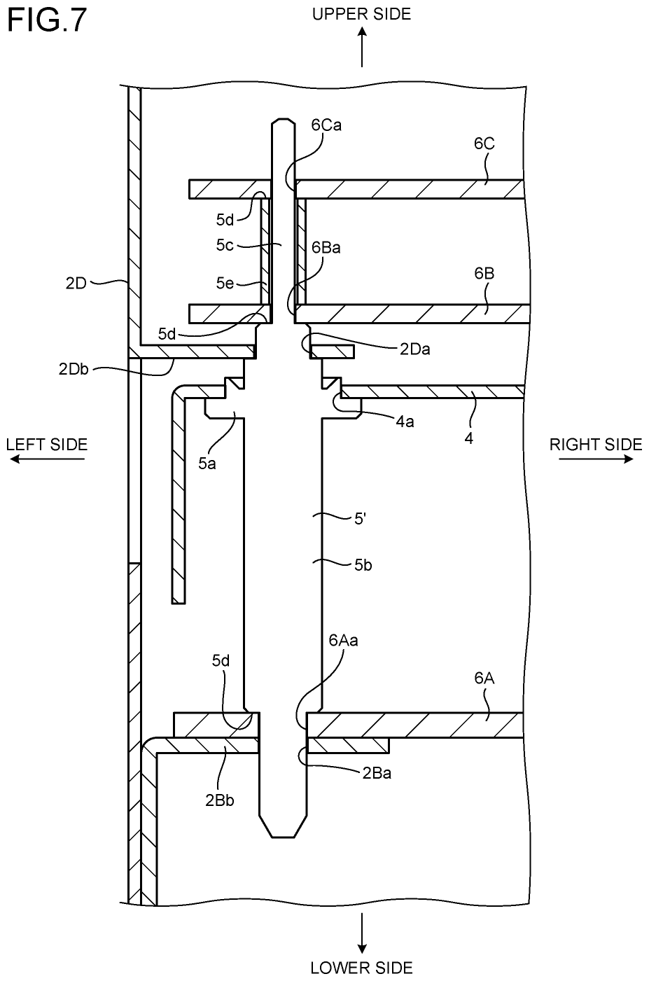

Moreover, a housing structure of one embodiment illustrated in FIG. 7 further includes the substrate 6C above the substrate 6B. Furthermore, the housing structure of one embodiment illustrated in FIG. 7 is configured such that a part of the stepped portions 5d is formed by a spacer 5e. The spacer 5e is formed in a cylindrical shape and inserted in the second shaft portion 5c between the substrate 6B and the substrate 6C, and, the stepped portion 5d for locking the periphery of one of the first positioning holes 6Ca of the substrate 6C is arranged on an upper end of the spacer 5e. Therefore, the housing structure of one embodiment illustrated in FIG. 7, is able to maintain, by the stepped portions 5d, intervals between components through which the pin members 5′ are inserted, and determine positions of the components in the extending directions of the pin members 5′. In particular, the housing structure of one embodiment illustrated in FIG. 7 includes the stepped portions 5d similarly to the housing structure of one embodiment illustrated in FIG. 6, but, at the stepped portion 5d for locking one of the first positioning holes 6Ca of the substrate 6C, it is possible to arrange the stepped portion 5d without reducing the diameter of the second shaft portion 5c, so that it is possible to increase strength of the second shaft portion 5c.

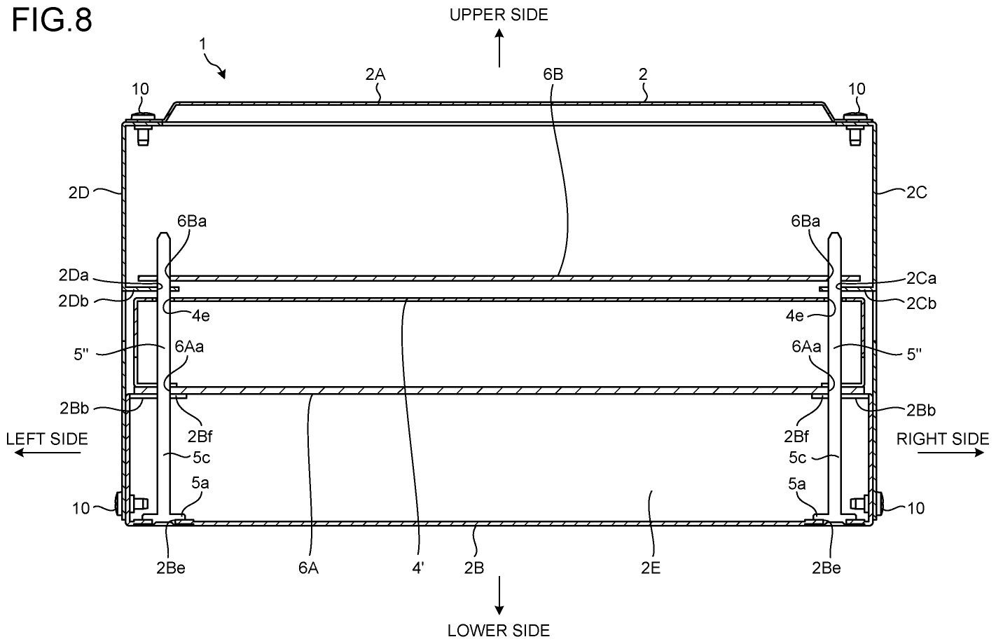

As illustrated in FIG. 8, the pin members 5″ include only the second shaft portions 5c that extend upward from the fixing portion 5a while maintaining a constant diameter. The fixing portions 5a of the pin members 5″ are fixed, by caulking, to fixing holes 2Be that are formed on the lower plate 2B. Furthermore, the second shaft portions 5c are inserted through notch portions 2Bf that are formed in the first fixing portions 2Bb, instead of the third positioning holes 2Ba as described above, on the lower plate 2B. The lower plate 2B to which the pin members 5″ are fixed is configured as a reference member. Furthermore, the reference member 4 as described above is configured as an intermediate member (first member) 4′ to which the substrates 6A and 6B are fixed, and the fixing holes 4a as described above are configured as first positioning holes 4e. Therefore, in the housing structure according to one embodiment illustrated in FIG. 8, the second shaft portion 5c of one of the pin members 5″ is inserted in one of the first positioning holes 6Aa of the substrate 6A, one of the first positioning holes 4e of the intermediate member 4′, the second positioning hole 2Ca of the right plate 2C, and one of the first positioning holes 6Ba of the substrate 6B in this order, and determines a position of each of the components with respect to the lower plate 2B that serves as the reference member. Furthermore, the second shaft portion 5c of the other one of the pin members 5″ is inserted in the other one of the first positioning holes 6Aa of the substrate 6A, the other one of the first positioning holes 4e of the intermediate member 4′, the second positioning hole 2Da of the left plate 2D, and the other one of the first positioning holes 6Ba of the substrate 6B in this order, and determines the position of each of the components with respect to the lower plate 2B that serves as the reference member. Meanwhile, in the housing structure according to one embodiment illustrated in FIG. 8, although not illustrated in the drawings, the pin members 5″ may be configured such that ends (upper ends) of the pin members 5″ are inserted in positioning holes that are formed in the upper plate 2A, and determines a position of the upper plate 2A with respect to the lower plate 2B that serves as the reference member.

In this manner, the housing structures according to one embodiment include the reference members 4 and 2B that constitute the housing 2, the pin members 5, 5′, and 5″ that are fixed to the reference members 4 and 2B and extend in a predetermined direction, the first positioning holes 6Aa, 6Ba, and 4e that are formed in the multiple first members (the substrate 6A, the substrate 6B, and the intermediate member 4′) included in the housing 2 and that allow insertion of the pin members 5, 5′, and 5″, and the second positioning holes 2Ca and 2 Da that are arranged in second members (the right plate 2C and the left plate 2D) that are oriented in different directions from the first members (the substrate 6A, the substrate 6B, and the intermediate member 4′) and included in the housing 2 and that allow insertion of the pin members 5, 5′, and 5″.

According the housing structure of one embodiment as described above, it is possible to determine, by the pin members 5, 5′, and 5″, positions of a large number of components that are oriented in different directions, such as the multiple first members (the substrate 6A, the substrate 6B, and the intermediate member 4′) and the multiple second members (the right plate 2C and the left plate 2D) that are oriented in different directions from the first members. As a result, the housing structure of one embodiment is able to improve dimensional accuracy of the housing 2. In addition, the housing structure of one embodiment is configured such that the pin members 5, 5′, and 5″ are inserted in the first positioning holes 6Aa, 6Ba, and 4e and the second positioning holes 2Ca and 2Da, so that it is possible to simplify a positioning structure, reduce man-hours at the time of assembly of the housing 2, and improve assembly performance. Furthermore, the housing structure of one embodiment uses the pin members 5, 5′, and 5″ as support columns, so that it is possible to improve rigidity of the housing 2.

Furthermore, in the housing structure of one embodiment, the pin members 5, 5′, and 5″ are arranged in multiple portions of the reference members 4 and 2B. Therefore, in the housing structure according to one embodiment, the pin members 5, 5′, and 5″ that serve as support columns are arranged in multiple portions, so that it is possible to further improve rigidity of the housing 2.

Furthermore, in the housing structure of one embodiment, the pin members 5′ and 5″ include the stepped portions 5d that lock peripheries of the first positioning holes 6Aa, 6Ba, and 4e and the second positioning holes 2Ca and 2Da. Therefore, in the housing structure according to one embodiment, it is possible to determine, by the stepped portions 5d, positions of the first members (the substrate 6A, the substrate 6B, and the intermediate member 4′) and the second members (the right plate 2C and the left plate 2D) in extending directions of the pin members 5′ and 5″.

Furthermore, in the housing structure of one embodiment, the reference member 4 is arranged between the multiple first members (the substrate 6A and the substrate 6B). Therefore, in the housing structure according to one embodiment, the pin members 5 and 5′ are arranged so as to extend in two opposite directions along the predetermined direction (up-down direction) with respect to the reference member 4, and it is possible to determine positions of the first members (the substrate 6A and the substrate 6B) in each of the directions.

Furthermore, in the housing structure of one embodiment, the reference member is configured by an external housing member (the lower plate 2B). Therefore, in the housing structure according to one embodiment, by adopting the external housing member (the lower plate 2B) as the reference member, it is possible to reduce the number of components, so that it is possible to improve assembly accuracy and simplify the configuration.

Moreover, in the housing structure of one embodiment, the second positioning holes 2Ca and 2 Da are arranged in the positioning pieces 2Cb and 2Db that are formed by bending a part of the second members (the right plate 2C and the left plate 2D). Therefore, in the housing structure according to one embodiment, by forming the second positioning holes 2Ca and 2 Da in the positioning pieces 2Cb and 2Db that are formed by bending a part of the second members (the right plate 2C and the left plate 2D), it is possible to reduce the number of components, and thus it is possible to improve assembly accuracy and simplify the configuration.

According to the present application, it is possible to determine positions of a large number of members that are oriented in different directions.

Although the application has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A housing structure comprising:
a reference member;
a pin member that is fixed to the reference member and that extends in a predetermined direction;
a first positioning hole that is provided for insertion of the pin member in each of multiple first members; and
a second positioning hole that is provided for insertion of the pin member in a second member.

2. The housing structure according to claim 1, wherein the pin member is provided in each of multiple portions in the reference member, and the first positioning hole is provided in each of multiple portions in each of the multiple first members.

3. The housing structure according to claim 1, wherein the pin member includes stepped portions that lock peripheries of the first positioning holes and the second positioning hole.

4. The housing structure according to claim 1, wherein the reference member is arranged between the multiple first members.

5. The housing structure according to claim 1, wherein the second positioning hole is provided in a positioning piece that is formed by bending a part of the second member.
